(19) United States
(12) Patent Application Publication
(10) Pub. No.: US 2024/0145537 A1
(43) Pub. Date: May 2, 2024

(54) SEMICONDUCTOR DEVICES WITH ADDITIONAL MESA STRUCTURES FOR REDUCED SURFACE ROUGHNESS

(71) Applicant: Wolfspeed, Inc., Durham, NC (US)

(72) Inventors: Rahul R. Potera, Apex, NC (US); Matthew McCain, Raleigh, NC (US); Madankumar Sampath, Durham, NC (US); Steven Rogers, Stem, NC (US)

(21) Appl. No.: 17/977,003

(22) Filed: Oct. 31, 2022

(51) Int. Cl. H01L 29/06; H01L 21/04; H01L 29/16; H01L 29/34; H01L 29/66; H01L 29/772

(52) U.S. Cl. CPC H01L 29/0661; H01L 21/045; H01L 21/046; H01L 21/0475; H01L 29/1608; H01L 29/34; H01L 29/66068; H01L 29/7722

(57) ABSTRACT

A method of forming a semiconductor device includes etching a semiconductor layer to form a plurality of mesa stripes in the semiconductor layer. The plurality of mesa stripes extend in a first direction and include mesa sidewalls that extend in the first direction and mesa surfaces at opposite ends of the mesa stripes. An additional mesa region is formed at an end of at least one of the mesa stripes. The additional mesa region is electrically insulated from the at least one of the mesa stripes. A semiconductor device structure includes a plurality of mesa stripes that extend in a first direction and include mesa sidewalls that extend in the first direction and mesa end surfaces at opposite ends of the mesa stripes. An additional mesa region that is electrically insulated from the at least one of the mesa stripes is at an end of at least one of the mesa stripes.

### FIELD

The present disclosure relates to semiconductor devices. In particular, the disclosure relates to silicon carbide semiconductor devices having trench/mesa structures.

### BACKGROUND

Power electronic devices, such as field effect transistors (FETs) manufactured using silicon carbide (SiC) are capable of high blocking voltages and high current carrying capability. In particular, SiC metal-oxide semiconductor field effect transistors (MOSFETs) can be used in high power, high speed switching applications, and can be used in applications requiring normally-off or normally-on switches.

For power devices having blocking voltages in the 600V-1000V range, SiC junction field effect transistors (JFETs) have two to three times smaller chip area than MOSFETs. SiC JFETs can also be manufactured with a simpler manufacturing process than MOSFETs, which can lead to lower manufacturing costs. Moreover, SiC JFET devices have no SiO₂—SiC interface, which may increase device reliability, as oxide layers may break down under high voltage operation. JFET devices have the drawback of being normally-on devices. However, their advantages may outweigh their disadvantages in power applications, such as high reliability Si—SiC heterogeneously integrated circuits.

### SUMMARY

A method of forming a semiconductor device according to some embodiments includes etching a semiconductor layer to form a plurality of mesa stripes in the semiconductor layer. The plurality of mesa stripes extend in a first direction and include mesa sidewalls that extend in the first direction and mesa end surfaces at opposite ends of the mesa stripes. An additional mesa region is formed at an end of at least one of the mesa stripes. The additional mesa region is electrically insulated from the at least one of the mesa stripes.

In some embodiments, the additional mesa region includes an electrically insulating portion of the at least one mesa stripe. The electrically insulating portion of the at least one mesa stripe may extend to an end surface of the at least one mesa stripe. The method may further include implanting deep level dopant ions into the at least one mesa stripe to form the electrically insulating portion of the at least one mesa stripe.

In some embodiments, the additional mesa region is separated from the at least one of the mesa stripes by a trench. The at least one of the mesa stripes may have an end surface facing toward the additional mesa region and having a first surface roughness, and the additional mesa region may have an outer surface facing away from the at least one mesa stripe and having a second surface roughness that is greater than the first surface roughness.

In some embodiments, the at least one of the mesa stripes has a side surface having a third surface roughness, wherein the second surface roughness of the outer surface of the additional mesa region is greater than the third surface roughness.

In some embodiments, the additional mesa region has a width that is about equal to a width of the at least one of the mesa stripes. The width of the additional mesa region may be about 1 to 1.5 microns.

In some embodiments, the mesa stripes are spaced apart by a plurality of trenches having a first width, and wherein additional mesa region has a second width that is about equal to the first width. The second width may be about 1 to 2 microns.

The method may further include forming a metal layer on the plurality of mesa stripes, wherein the metal layer is separated from the additional mesa region. Forming the metal layer may include forming an interlayer dielectric layer on the plurality of mesa stripes, forming an opening in the interlayer dielectric layer above the plurality of mesa stripes, wherein the opening in the interlayer dielectric layer exposes the plurality of mesa stripes and does not expose the additional mesa region, and depositing the metal layer in the opening.

The method may further include implanting dopants into a region of the semiconductor layer to form a current spreading layer in the semiconductor layer beneath the plurality of mesa stripes, wherein the region of the semiconductor layer is within an area bounded by the opening in the interlayer dielectric layer. The opening in the interlayer dielectric layer may overlap the region of the semiconductor layer in which the current spreading layer is formed by a distance of about 5 to 10 microns.

The additional mesa region may have a length in the first direction parallel to the at least one of the mesa stripes that is less than a width of the at least one of the mesa stripes in a second direction perpendicular to the at least one of the mesa stripes.

The additional mesa region may overlap end surfaces of at least two of the plurality of the mesa stripes.

In some embodiments, the additional mesa region includes a mesa dam that at least partially surrounds the plurality of the mesa stripes.

The semiconductor device may include a junction field effect transistor, JFET, device or a metal oxide semiconductor field effect transistor, MOSFET, device.

A semiconductor device structure according to some embodiments includes a plurality of mesa stripes, wherein the plurality of mesa stripes extend in a first direction and include mesa sidewalls that extend in the first direction and mesa end surfaces at opposite ends of the mesa stripes, and an additional mesa region at an end of at least one of the mesa stripes. The additional mesa region is electrically insulated from the at least one of the mesa stripes.

The additional mesa region may include an electrically insulating portion of the at least one mesa stripe. The electrically insulating portion of the at least one mesa stripe may extend to an end surface of the at least one mesa stripe. The additional mesa region may be doped with deep level dopant ions.

In some embodiments, the additional mesa region is separated from the at least one of the mesa stripes by a trench. The at least one of the mesa stripes may have an end surface facing toward the additional mesa region and having a first surface roughness, and the additional mesa region may have an outer surface facing away from the at least one mesa stripe and having a second surface roughness that is greater than the first surface roughness.

In some embodiments, the at least one of the mesa stripes has a side surface having a third surface roughness, wherein the second surface roughness of the outer surface of the additional mesa region is greater than the third surface roughness. In some embodiments, the additional mesa region has a width that is about equal to a width of the at least one of the mesa stripes.

The width of the additional mesa region may be about 1 to 1.5 microns.

The mesa stripes may be spaced apart by a plurality of trenches having a first width, and additional mesa region may have a second width that is about equal to the first width. The second width may be about 1 to 2 microns.

The semiconductor device structure may further include an interlayer dielectric layer on the plurality of mesa stripes, the interlayer dielectric layer having an opening above a portion of the plurality of mesa stripes, and a metal layer in the opening and contacting the plurality of mesa stripes, wherein the metal layer is separated from the additional mesa region.

The semiconductor device structure may further include a current spreading layer in the semiconductor layer beneath the plurality of mesa stripes, wherein the region of the semiconductor layer is within an area bounded by the opening in the interlayer dielectric layer. The opening in the interlayer dielectric layer may overlap the region of the semiconductor layer in which the current spreading layer is formed by a distance of about 5 to 10 microns.

In some embodiments, the additional mesa region has a length in the first direction parallel to the at least one of the mesa stripes that is less than a width of the at least one of the mesa stripes in a second direction perpendicular to the at least one of the mesa stripes.

The additional mesa region may overlap end surfaces of at least two of the plurality of the mesa stripes.

In some embodiments, the additional mesa region includes a mesa dam that surrounds the plurality of the mesa stripes.

The semiconductor device structure may be a junction field effect transistor, JFET, device structure or a metal oxide semiconductor field effect transistor, MOSFET, device structure.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 is a cross-sectional illustration of a vertical JFET device structure.

FIGS. 2A and 2B are perspective drawings of portions of JFET device having a plurality of mesa stripes with surface roughness on the sidewalls.

FIG. 3A schematically illustrates aspects of a layout of a JFET semiconductor device structure including a plurality of mesa stripes in plan view.

FIG. 3B is a partial cross-sectional view taken along line A-A′ of FIG. 3A.

FIG. 4 schematically illustrates aspects of a device layout in plan view according to some embodiments.

FIG. 5 is a flowchart illustrating operations for fabricating a silicon carbide semiconductor device according to some embodiments.

FIGS. 6 to 10 schematically illustrate aspects of device layouts in plan view according to further embodiments.

FIGS. 11 and 12 schematically illustrate aspects of device layouts in plan view according to further embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices, such as MOSFETs, insulated gate bipolar transistors (IGBTs) and other types of devices.

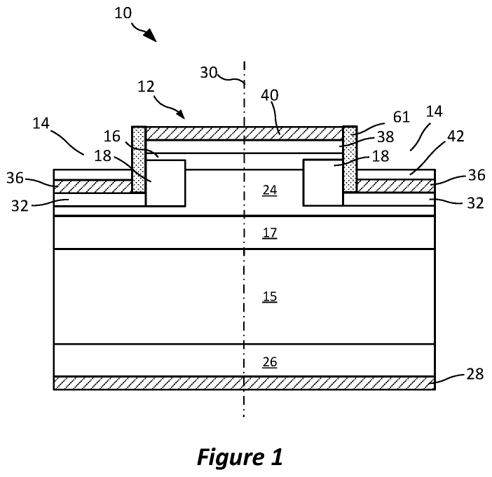

An n-channel vertical JFET structure 10 is shown in FIG. 1. The vertical JFET structure 10 includes an n+ drain layer 26 on which an n− drift layer 15 is formed. An n+ current spreading layer (CSL) 17 may optionally be provided on the drift layer 15. The CSL is a higher doped n-type region in the channel region of the JFET at the drain end. The CSL 17 allows for a better trade-off between blocking voltage (lower doping of the drift region) and threshold voltage (V_{T}) & R_{DSON} (higher doping of the channel) than if the same doping were used in both the drift region and the channel.

An n-type channel region 24 is on the drift layer 15 (and the CSL 17 if present), and an n+ source layer 16 is on the channel region 24. An n++ source contact layer 38 is on the n+ source layer 16. A drain ohmic contact 28 is on the drain layer 26, and a source ohmic contact 40 is on the source contact layer 38. The channel region 24, source layer 16 and source contact layer 38 are provided as part of a mesa 12 above the drift layer 15. Trenches 14 are formed in the structure 10 adjacent the mesa 12.

A p+ gate region 18 is provided as part of the mesa 12 adjacent the channel region 24. A p++ gate contact region 32 is provided adjacent the gate region 18, and a gate ohmic contact 36 is formed on the gate contact region 32. A passivation layer 42 is on the gate ohmic contact 36 and the gate contact region 32. Silicon nitride spacer layers 61 are provided on sidewalls of the mesa 12.

The vertical JFET unit cell structure 10 is symmetrical about the axis 30 and includes two gate regions 18 as part of the mesa 12 on opposite sides of the channel region 24.

The channel of the vertical JFET structure 10 is formed within the mesa 12. The channel width is into the plane of FIG. 1, and the channel length is in the vertical direction. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 16 and the drain layer 26 is modulated by applying a reverse bias to the gate region 18 relative to the source layer 16. To switch off an n-channel device such as the JFET structure 10, a negative gate-to-source voltage, or simply gate voltage (VGs) is applied to the gate region 18. When no voltage is applied to the gate region 18, charge carriers can flow freely from the source layer 16 through the channel region 24 and the drift layer 15 to the drain layer 26.

When the device is reverse biased, source-gate leakage current may flow across both the bulk junction and the surface junction on the mesa sidewall. Imperfections on the mesa sidewall (such as roughness, surface traps, etc.) may lead to source-gate surface leakage being the dominant source of leakage, which determines the maximum reverse voltage that the gate-source junction can support. It is therefore desirable to reduce the roughness of mesa sidewalls and passivate the sidewalls to reduce the concentration of surface traps.

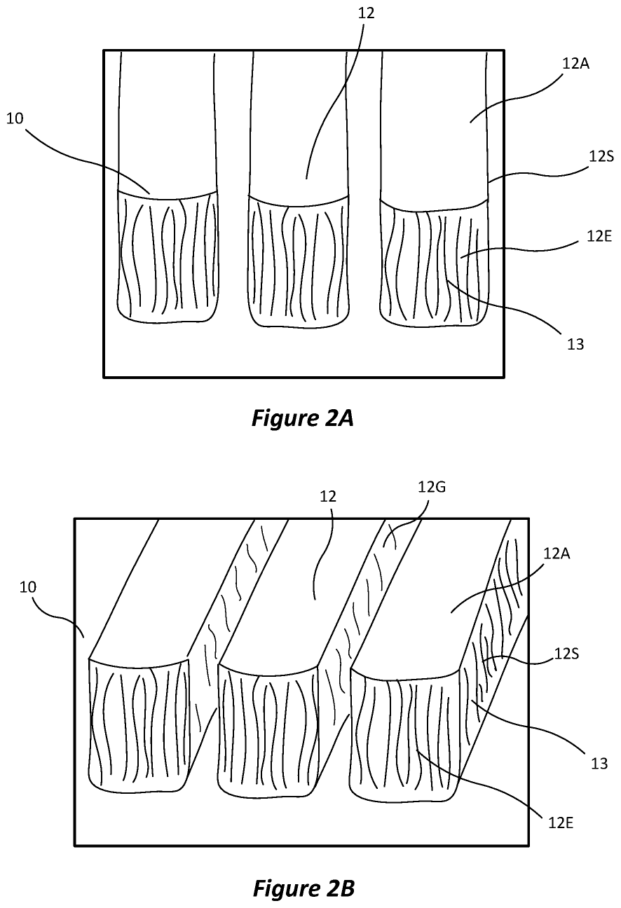

FIGS. 2A and 2B are perspective views of a portion of JFET device 10 having a plurality of parallel mesas 12, which are formed as mesa stripes on a substrate. In the following description, the terms “mesa” and “mesa stripe” are used interchangeably to refer to the mesas of a semiconductor device that extend in a longitudinal direction. Mesa stripes may also be referred to as mesa “fingers” due to their elongated shape. Although described herein primarily with reference to JFET devices, it will be appreciated that the inventive concepts may be applied to other types of semiconductor devices having mesa or mesa stripe structures, such as vertical MOSFET structures.

As can be seen in FIGS. 2A and 2B, end surfaces 12E of the plurality of mesa stripes 12 and outer sidewalls 12S of the outermost mesa stripes 12A of the plurality of mesa stripes 12 of a semiconductor device 10 may experience an enhanced level of surface roughness 13 relative to outer sidewalls 12G of the inner mesa stripes 12 when the mesas are formed. While not wishing to be bound by a particular theory of operation, it is presently believed that the enhanced surface roughness is due to the fact that the outer sidewalls 12S of the mesa stripes 12 are exposed and are not shielded by other mesas during a plasma etch process used to form the mesa stripes 12. That is, it is presently believed that the plasma used in the plasma etch process may be channeled in the spaces between the mesa stripes 12, and may provide a more anisotropic etch in those areas, while the plasma outside the mesas may provide a more isotropic etch that causes more etch damage on the sidewalls of the outermost mesa stripes 12A.

Similarly, the end surfaces 12E of the mesa stripes may experience higher levels of roughness than the shielded sidewalls of inner ones of the mesa stripes 12.

Manufacturing technology limits the extent to which surface roughness of trench sidewalls can be reduced, especially when that roughness is limited to certain regions of the device. It is therefore of interest to inactivate those regions of the device to prevent them from participating in active device operation.

One approach that has been employed to reduce the impact of increased surface roughness on outer sidewalls of the outermost mesas of a plurality of mesa stripes is to avoid connecting the outermost mesa stripes to the source metallization of the device through appropriate masking and metallization techniques.

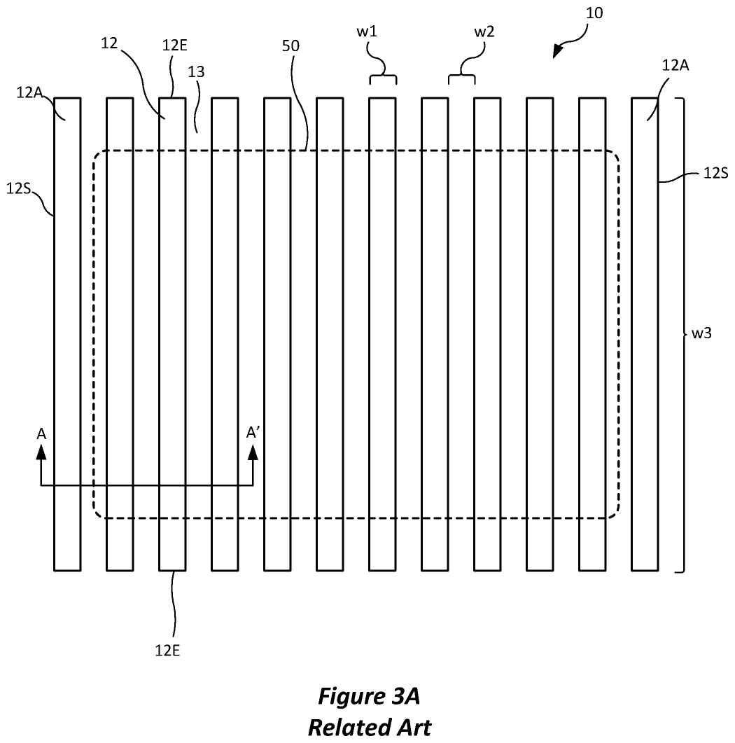

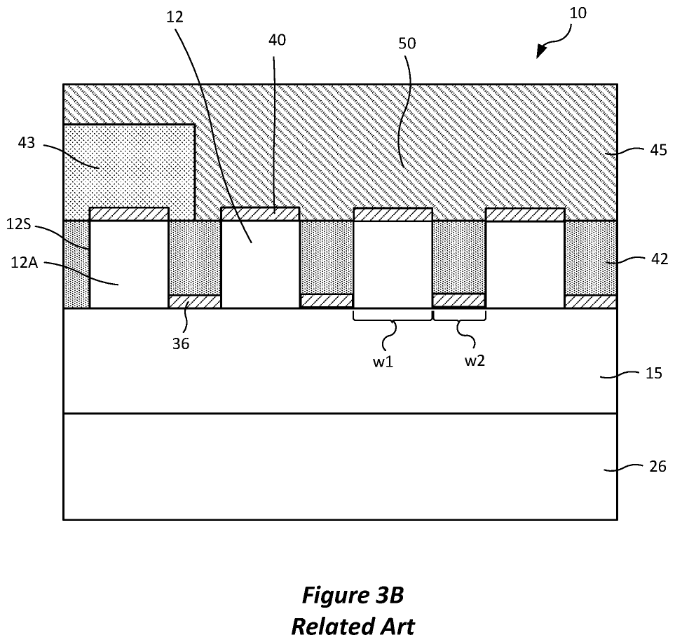

FIG. 3A schematically illustrates a JFET semiconductor device 10 including a plurality of mesa stripes 12 in plan view, and FIG. 3B is a partial cross-sectional view taken along line A-A′ of FIG. 3A. In FIGS. 3A and 3B, the mesa stripes have a width w1 and a length w3 and are spaced apart laterally by a trench width w2.

Referring to FIGS. 3A and 3B, outermost mesa stripes 12A of the plurality of mesa stripes 12 may have increased roughness on their outermost sidewalls. To reduce leakage current due to the enhanced roughness on the outermost mesa stripes 12A, the mesa stripes 12A may excluded from the operating area of the device by not connecting the mesa stripes 12A to the source metallization of the device. In particular, before a source metal layer is deposited, the tops of the mesa stripes may be exposed by forming an interlayer dielectric layer 43 (FIG. 3B) over the mesa stripes and forming an opening 50 in the interlayer dielectric that exposes inner ones of the mesa stripes 12 but not the outermost mesa stripes 12A. Therefore, when a source metallization 45 is deposited on the device structure, it will contact the ohmic contacts 40 on the mesa stripes 12, but will not contact the ohmic contacts 40 on the outermost mesa stripes 12A. Because the source metallization 45 does not contact the ohmic contacts 40 on the outermost mesa stripes 12A, current will not flow through the outermost mesa stripes 12A in the ON state of the device and gate-source leakage current will not flow through those portions of the device in the OFF state.

However, even though the source metallization 45 does not extend all the way to the end surfaces 12E of the inner mesa stripes 12, because the ohmic contacts 40 do extend to the end surfaces 12E of the inner mesa stripes 12, the end surfaces of the mesa stripes 12 are still electrically active regions. Thus, leakage current can still flow along the end surfaces 12E of the inner mesa stripes 12. Henceforth, the mesa stripes 12 that are electrically connected to the source metallization 45 may be referred to as “active mesa stripes 12.”

To reduce source-gate leakage at the ends of the active mesa stripes 12 of a device 10, some embodiments provide additional mesa regions at the ends of the mesa stripes 12 to protect the end surfaces of the mesa stripes 12 during a plasma etch process to form the mesa stripes 12 in a similar manner as that in which the outermost mesa stripes 12A protect the sidewalls of the inner mesa stripes during the plasma etch process. The additional mesa regions may be formed using the same etch process used to form the mesa stripes 12. Thus, no additional process steps may be required to form the additional mesa regions.

In some embodiments, the additional mesa regions may be provided at the ends of the mesa stripes.

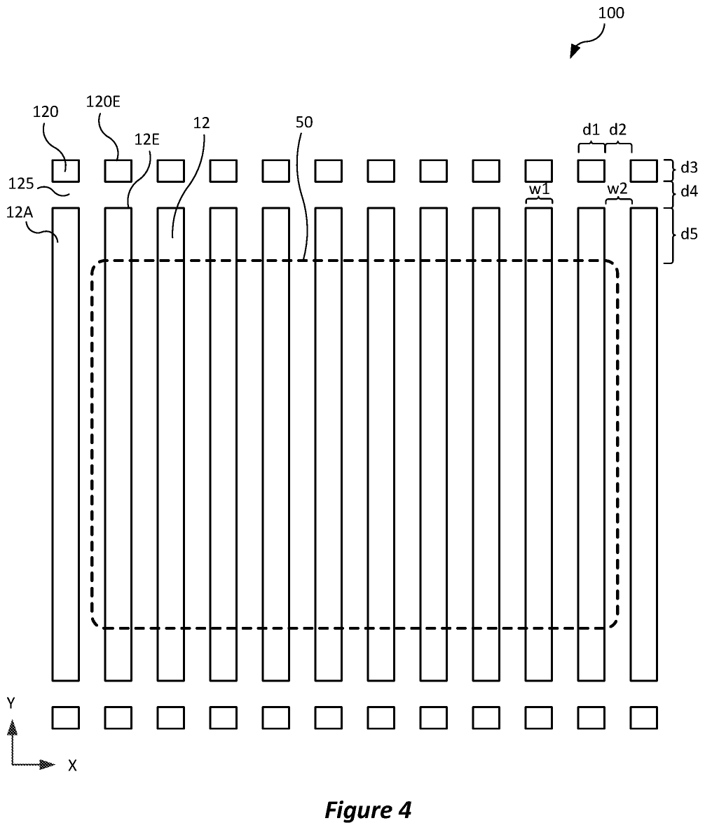

For example, referring to FIG. 4, an example of a device layout 100 according to some embodiments is illustrated. As shown therein, in some embodiments, additional mesa regions 120 are provided adjacent the end surfaces 12E of each of the mesa stripes 12 of the device 100. The additional mesa regions 120 may be formed by etching a trench 125 that runs in a direction perpendicular to the mesa stripes 12 at the end of the structure. For example, as illustrated in FIG. 4, the mesa stripes 12 may extend in a Y-direction, and the trench 125 separating the additional mesa regions 120 from the mesa stripes 12 may extend in the X-direction.

The trench 125 may have a width d4 that is similar to that of the trenches between the mesa stripes (i.e., similar to the width w2 shown in FIG. 3A).

The additional mesa regions 120 may have widths d1 (in a direction perpendicular to the mesa stripes 12) that are similar to the widths w1 of the mesa stripes 12 shown in FIG. 3A, and may be separated by trenches or gaps having a width d2 that is similar to the widths w2 of the trenches between the mesa stripes 12 shown in FIG. 3A.

The additional mesa regions 120 may have lengths d3 (in a direction parallel to the mesa stripes 12) that are about 1 micron to 1.5 microns. The additional mesa regions 120 may be separated from the end surfaces 12E of the mesa stripes 12 by a trenches having a length d4 of about 1 to 2 microns.

Due to the presence of the additional mesa regions 120, the end surfaces 12E of the mesa stripes 12 facing the additional mesa regions 120 may have a reduced surface roughness relative to the exposed end surfaces 120E of the additional mesa regions that face away from the mesa stripes 12. Similarly, the side surfaces of the mesa stripes 12 (except for the outer side surfaces of the outermost mesa stripes 12A) may have a reduced surface roughness relative to the exposed end surfaces 120E of the additional mesa regions 120 that face away from the mesa stripes 12.

The source metallization 45 may be formed using an interlayer dielectric mask layer that excludes opening above the additional mesa regions 120 at the end of each mesa stripe 12 as well as the outermost mesa stripes 12A on each side of the device structure. In particular, the opening 50 in the interlayer dielectric layer 43 (FIG. 3B) that defines the location of the source metallization may underlap the ends of the mesa stripes 12 by a distance d5 of about 5 to 10 microns.

Some embodiments may isolate the source region at the ends of the mesa stripes 12 as well as isolating the source region of the outermost mesa stripes 12A. In some embodiments, the additional mesa regions 120 at the ends of the mesa stripes 12 may be separated from mesa stripes 12 by a width d4 that is equal to the width of the trenches 13 between the mesa stripes 12. By forming the additional mesa regions 120 close to the mesa stripes 12, the additional mesa regions 120 may shield the end surfaces 12E of the mesa stripes 12 from the etch/plasma damage that may cause enhanced surface roughness. Enhanced surface roughness will be present on the exposed end surfaces 120E of the additional mesa regions 120, but the source contacts 40 on the additional mesa regions 120 are not connected to the source metallization 45 of the device 100, and hence will not contribute to source current or reverse leakage current. Some example values for pertinent device dimensions are shown in Table 1. Sub-ranges are provided as more precise dimensions in some embodiments.

TABLE 1
Example Device Dimensions

| Feature | Range | | Sub-range | |
|---|---|---|---|---|
| Mesa height | 1.5-2.5 | microns | 1.8-2.2 | microns |
| Mesa width (w1) | 1-1.5 | microns | 1.2-1.4 | microns |
| Trench width (d2, d4, w2) | 1-2 | microns | 1.2-1.8 | microns |
| Mesa length (w3) | 500-1500 | microns | 800-1200 | microns |
| Width of additional mesa | 1-1.5 | microns | 1.2-1.4 | microns |
| region at end of | | | | |
| mesa stripe (d1) | | | | |
| Length of additional mesa | 1-1.5 | microns | 1.2-1.4 | microns |
| region at end of | | | | |
| mesa stripe (d3) | | | | |
| Underlap of interlayer | 5-10 | microns | 7-8 | microns |
| dielectric opening from | | | | |
| end of mesa stripe (d5) | | | | |

The additional mesa regions 120 may be formed by appropriately designing the etch mask used to form the mesa stripes 12. Accordingly, some embodiments described herein may be implemented using only design and layout techniques, which may involve no additional process burden and may add very little area overhead to the device.

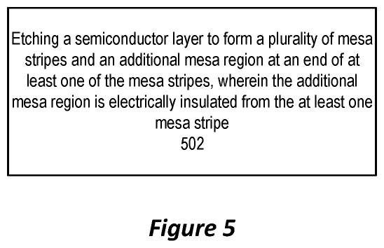

FIG. 5 illustrates operations according to some embodiments. In particular, a method of forming a semiconductor device according to some embodiments includes etching (block 502) a semiconductor layer to form a plurality of mesa stripes, wherein the plurality of mesa stripes extend in a first direction and include mesa sidewalls that extend in the first direction and mesa end surfaces at opposite ends of the mesa stripes. The etching process forms an additional mesa region at an end of at least one of the mesa stripes. The additional mesa region is separated from the at least one of the mesa stripes by a trench.

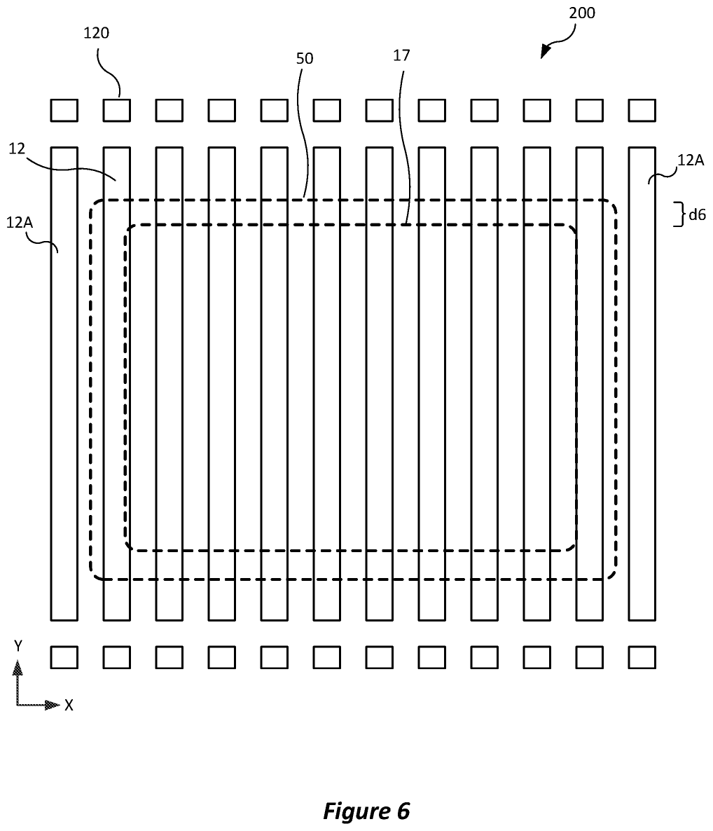

FIG. 6 illustrates a device layout 200 according to further embodiments in which the doping of the CSL 17 (FIG. 1) is excluded from both the additional mesa regions 120 and the mesas 12A at the ends of the active mesa stripes 12. Similar to the embodiment shown in FIG. 4, the opening 50 in the interlayer dielectric layer 43 for the source metallization 45 excludes the outermost mesas 12A and the additional mesa regions 120 that are to be inactivated. The interlayer dielectric layer opening 50 may overlap the doping region of the CSL 17 by a distance d6 of about 5 to 10 microns.

If the CSL doping is excluded from a part of the JFET structure, then the resultant lighter doping in the excluded region will cause the channel to pinch-off at a higher (less negative) gate voltage for an n-channel JFET. That is, the device will locally have a higher threshold voltage. When threshold voltage is locally higher in a certain region of the device, the on-state gate voltage can be chosen such that that part of the device is off even when rest of the device is on. In this embodiment of the invention, by excluding CSL from the additional mesa regions 120 and the outermost mesa stripes 12A, the source-to-drain current from those mesas can also be blocked or obstructed from contributing to JFET terminal current. Some example values for doping of the CSL 17 and the drift layer 15 in some embodiments are shown in Table 2. Sub-ranges are provided as more precise parameters in some embodiments.

TABLE 2
Example design parameters

| Feature | Range | Sub-range |
|---|---|---|
| CSL doping | 4-8E16/cm3 | 5-6E16/cm3 |
| Drift layer doping | 0.5-1.5E16/cm3 | 0.8-1.2E16/cm3 |
| Overlap of interlayer | 5-10 microns | 7-8 microns |
| dielectric layer opening | | |
| over CSL opening (d6) | | |

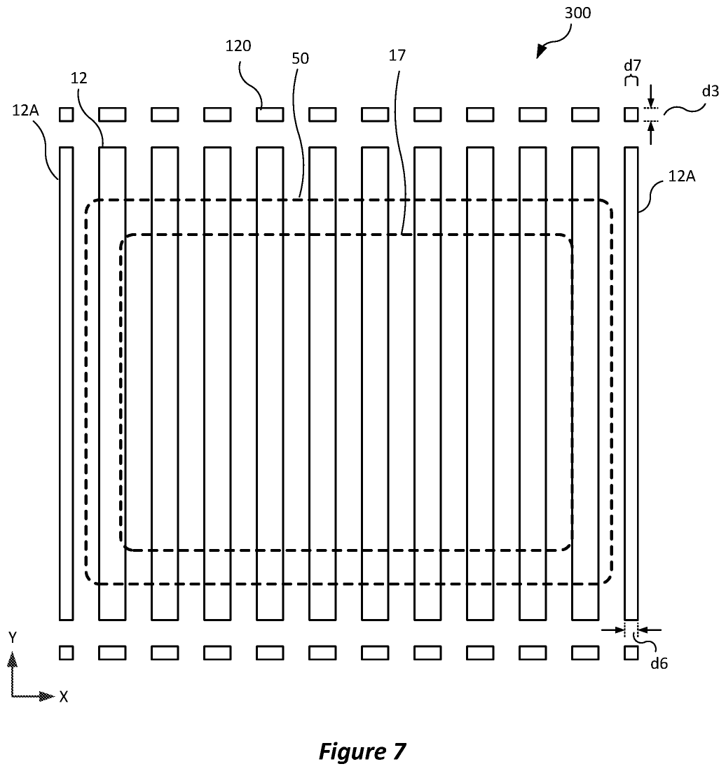

FIG. 7 illustrates a device layout 300 of an embodiment in which the length d3 of the additional mesa regions 120 and the width d7 of the outermost mesa stripes 12A are reduced relative to the width w1 of the active mesa stripes 12. In the embodiment shown in FIG. 7, the additional mesa regions 120 at the and the outermost mesa stripes 12A are narrower in width. If the mesa width is reduced in a part of the trench JFET, then the resultant narrower channel and lesser charge in the channel at that location will cause the channel to pinch-off at a higher (lower negative) gate voltage (for an n-channel JFET). That is the device will locally have a higher threshold voltage. When the threshold voltage is locally higher in a certain region of the device, the on-state gate voltage can be chosen such that that part of the device is off even when rest of the device is on. In this embodiment, by narrowing the inactive mesas 12A and the additional mesa regions 120, the source-to-drain current from those regions can also be blocked or obstructed from contributing to the JFET terminal current. Narrowing the inactive mesas 12A and the additional mesa regions 120 can also reduce the overall area of the device. Some example values for pertinent device dimensions for this embodiment are shown in Table 3. Sub-ranges are provided as more precise dimensions in some embodiments.

TABLE 3
Example device dimensions

| Feature | Range | Sub-range |
|---|---|---|
| Length of additional mesa | 0.8-1 microns | 0.85-0.95 microns |
| regions (d3) | | |
| Width of outermost mesa | 0.8-1 microns | 0.85-0.95 microns |
| stripes (d7) | | |

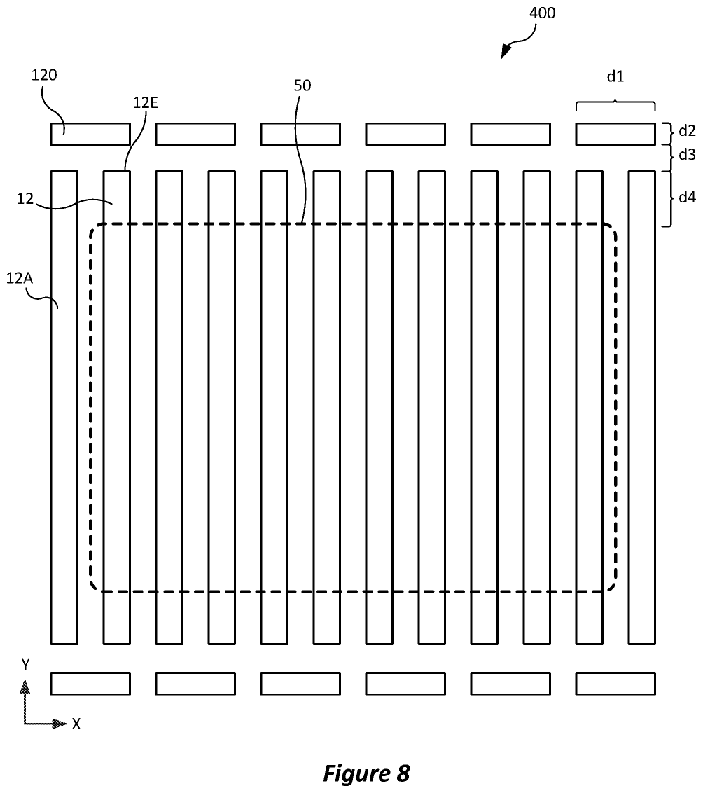

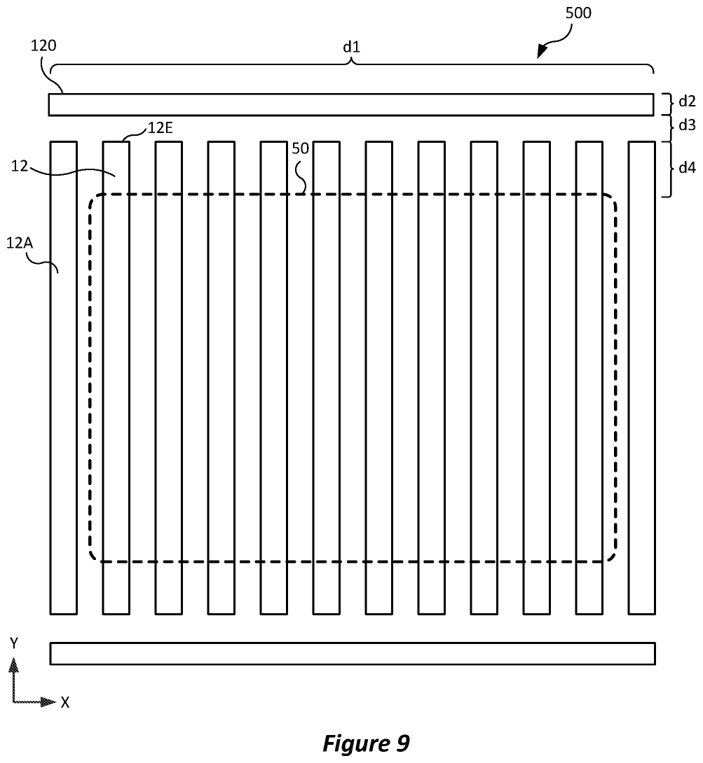

FIGS. 8 and 9 illustrate embodiments in which the additional mesa regions 120 are wider than the mesa stripes 12. For example, FIG. 8 illustrates a device layout 400 according to some embodiments in which the additional mesa regions 120 have a width d1 that is large enough that each additional mesa region 120 covers and protects the end surfaces 12E of two of the active mesa stripes 12. Similarly, FIG. 9 illustrates a device layout 500 according to some embodiments in which the additional mesa regions 120 have a width d1 that is large enough to span the entire width of the device structure. Thus, a single additional mesa region 120 may protect the end surfaces 12E of all of the active mesa stripes 12 of the device on one side of the structure. Other lengths, or combinations of lengths, of the additional mesa regions 120 are possible and are contemplated within the scope of the inventive concepts described herein.

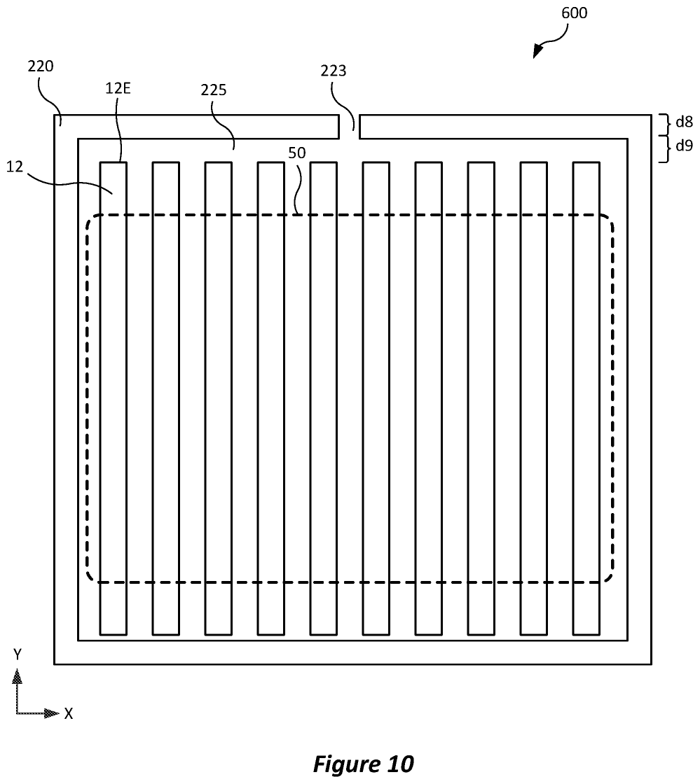

FIG. 10 illustrates a device layout 600 according to an embodiment in which a continuous protective mesa dam 220 is formed to surround the active mesa stripes 12. The mesa dam 220 may perform the function of both the outermost mesa stripes 12A and the additional mesa regions 120 shown in previous embodiments of protecting the sides and end surfaces of the active mesa stripes 12 from enhanced surface damage. The mesa dam 220 may be formed in the same etch process as the active mesa stripes 12 and may have a width d8 of about 0.8 to 1.5 microns and be spaced apart from the active mesa stripes 12 by a trench 235 having a width d9 of about 1 to 2 microns that surrounds the active mesa stripes 12. In some embodiments, there may be one or more openings 223 in the mesa dam 220 to allow access to the gate pad of the device. Thus, the mesa dam 220 may not be continuous around the mesa stripes 12.

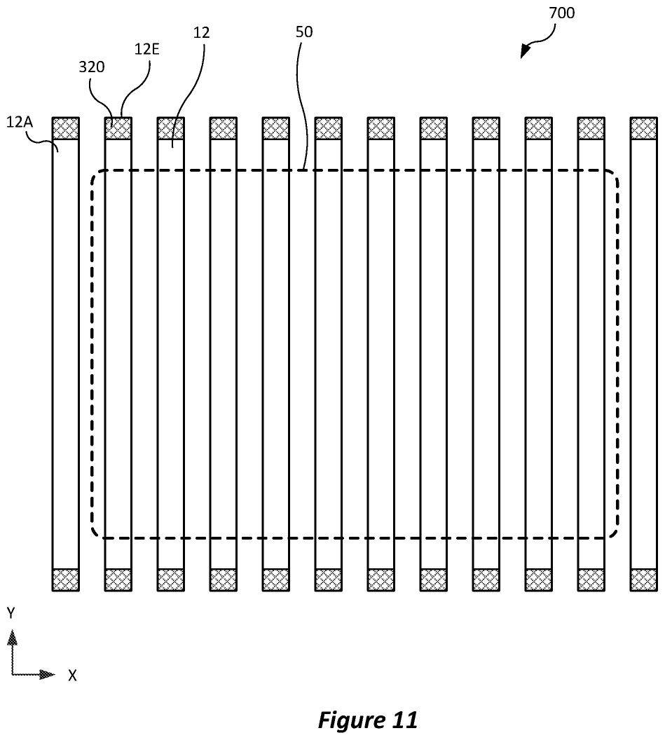

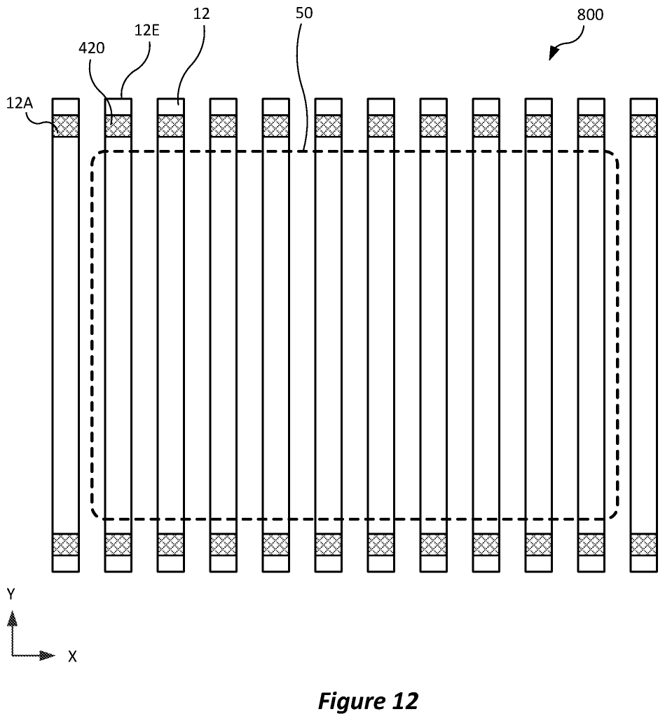

FIGS. 11 and 12 schematically illustrate aspects of device layouts in plan view according to further embodiments. In particular, FIG. 11 illustrates a device layout 700 according to an embodiment in which the additional mesa regions comprise end portions 320 of the mesa stripes 12 that are electrically inactivated (or deadened) to be electrically insulating or semi-insulating so that current does not substantially flow across the end surfaces 12E of the mesa stripes 12. Since the additional mesa regions 320 of the mesa stripes 12 are electrically insulating or semi-insulating, etch damage on the end surfaces 12E of the mesa stripes 12 may not substantially contribute to leakage current in reverse bias conditions.

FIG. 12 illustrates a device layout 800 according to an embodiment in which additional mesa regions 420 of the mesa stripes 12 near the end surfaces 12E of the mesa stripes are electrically inactivated (or deadened) to be electrically insulating or semi-insulating so that current does not substantially flow to the end surfaces 12E of the mesa stripes 12 from the active portions of the mesa stripes 12. Since the end surfaces 12E of the mesa stripes 12 are separated from active portions of the mesa stripes 12 by the additional mesa regions 420, etch damage on the end surfaces 12E of the mesa stripes 12 may not substantially contribute to leakage current in reverse bias conditions.

The additional mesa regions 320. 420 may be made electrically insulating or semi-insulating by, for example, implanting deep level dopant ions, such as iron and/or carbon, into the additional mesa regions 320, 420 at sufficient concentrations to make the regions substantially electrically non-conductive. Although illustrated in FIGS. 11 and 12 as being outside the opening 50 in the interlayer dielectric layer 43 in which the source contact metal contacts the mesa stripes 12, it will be appreciated that the electrically insulating additional mesa regions 320, 420 of the mesa stripes 12 may extend all the way to, or under/into, the opening 50 in the interlayer dielectric layer 43.

Although embodiments of the inventive concepts have been described in considerable detail with reference to certain configurations thereof, other versions are possible. Accordingly, the spirit and scope of the invention should not be limited to the specific embodiments described above.

1. A method of forming a semiconductor device, comprising:
etching a semiconductor layer to form a plurality of mesa stripes in the semiconductor layer, wherein the plurality of mesa stripes extend in a first direction and comprise mesa sidewalls that extend in the first direction and mesa end surfaces at opposite ends of the mesa stripes;
wherein an additional mesa region is formed adjacent an end surface of at least one of the mesa stripes; and
wherein the additional mesa region is electrically insulated from the at least one of the mesa stripes.

2. The method of claim 1, wherein the additional mesa region comprises an electrically insulating portion of the at least one mesa stripe.

3. The method of claim 2, wherein the electrically insulating portion of the at least one mesa stripe extends to an end surface of the at least one mesa stripe.

4. The method of claim 2, further comprising implanting deep level dopant ions into the at least one mesa stripe to form the electrically insulating portion of the at least one mesa stripe.

5. The method of claim 1, wherein the additional mesa region is separated from the at least one of the mesa stripes by a trench.

6. The method of claim 5, wherein the at least one of the mesa stripes has an end surface facing toward the additional mesa region and having a first surface roughness, and the additional mesa region has an outer surface facing away from the at least one mesa stripe and having a second surface roughness that is greater than the first surface roughness.

7. The method of claim 6, wherein the at least one of the mesa stripes has a side surface having a third surface roughness, wherein the second surface roughness of the outer surface of the additional mesa region is greater than the third surface roughness.

8. The method of claim 5, wherein the additional mesa region has a width that is about equal to a width of the at least one of the mesa stripes.

9. The method of claim 8, wherein the width of the additional mesa region is about 1 to 1.5 microns.

10. The method of claim 5, wherein the mesa stripes are spaced apart by a plurality of trenches having a first width, and wherein additional mesa region has a second width that is about equal to the first width.

11. The method of claim 10, wherein the second width is about 1 to 2 microns.

12. The method of claim 1, further comprising:
forming a metal layer on the plurality of mesa stripes, wherein the metal layer is separated from the additional mesa region.

13. The method of claim 12, wherein forming the metal layer comprises:
forming an interlayer dielectric layer on the plurality of mesa stripes;
forming an opening in the interlayer dielectric layer above the plurality of mesa stripes, wherein the opening in the interlayer dielectric layer exposes the plurality of mesa stripes and does not expose the additional mesa region; and
depositing the metal layer in the opening.

14. The method of claim 13, further comprising:
implanting dopants into a region of the semiconductor layer to form a current spreading layer in the semiconductor layer beneath the plurality of mesa stripes;
wherein the region of the semiconductor layer is within an area bounded by the opening in the interlayer dielectric layer.

15. The method of claim 14, wherein the opening in the interlayer dielectric layer overlaps the region of the semiconductor layer in which the current spreading layer is formed by a distance of about 5 to 10 microns.

16. The method of claim 5, wherein the additional mesa region has a length in the first direction parallel to the at least one of the mesa stripes that is less than a width of the at least one of the mesa stripes in a second direction perpendicular to the at least one of the mesa stripes.

17. The method of claim 5, wherein the additional mesa region overlaps end surfaces of at least two of the plurality of the mesa stripes.

18. The method of claim 5, wherein the additional mesa region comprises a mesa dam that at least partially surrounds the plurality of the mesa stripes.

19. The method of claim 1, wherein the semiconductor device comprises a junction field effect transistor, JFET, device.

20. The method of claim 1, wherein the semiconductor device comprises a metal oxide semiconductor field effect transistor, MOSFET, device.

21. A semiconductor device structure, comprising:
a plurality of mesa stripes, wherein the plurality of mesa stripes extend in a first direction and comprise mesa sidewalls that extend in the first direction and mesa end surfaces at opposite ends of the mesa stripes; and
an additional mesa region adjacent an end surface of at least one of the mesa stripes, wherein the additional mesa region is electrically insulated from the at least one of the mesa stripes.

22. The semiconductor device structure of claim 21, wherein the additional mesa region comprises an electrically insulating portion of the at least one mesa stripe.

23. The semiconductor device structure of claim 22, wherein the electrically insulating portion of the at least one mesa stripe extends to an end surface of the at least one mesa stripe.

24. The semiconductor device structure of claim 22, wherein the additional mesa region is doped with deep level dopant ions.

25. The semiconductor device structure of claim 21, wherein the additional mesa region is separated from the at least one of the mesa stripes by a trench.

26. The semiconductor device structure of claim 25, wherein the at least one of the mesa stripes has an end surface facing toward the additional mesa region and having a first surface roughness, and the additional mesa region has an outer surface facing away from the at least one mesa stripe and having a second surface roughness that is greater than the first surface roughness.

27. The semiconductor device structure of claim 26, wherein the at least one of the mesa stripes has a side surface having a third surface roughness, wherein the second surface roughness of the outer surface of the additional mesa region is greater than the third surface roughness.

28. The semiconductor device structure of claim 25, wherein the additional mesa region has a width that is about equal to a width of the at least one of the mesa stripes.

29. The semiconductor device structure of claim 28, wherein the width of the additional mesa region is about 1 to 1.5 microns.

30. The semiconductor device structure of claim 25, wherein the mesa stripes are spaced apart by a plurality of trenches having a first width, and wherein additional mesa region has a second width that is about equal to the first width.

31. The semiconductor device structure of claim 30, wherein the second width is about 1 to 2 microns.

32. The semiconductor device structure of claim 21, further comprising:
an interlayer dielectric layer on the plurality of mesa stripes, the interlayer dielectric layer having an opening above a portion of the plurality of mesa stripes; and
a metal layer in the opening and contacting the plurality of mesa stripes, wherein the metal layer is separated from the additional mesa region.

33. The semiconductor device structure of claim 32, further comprising:
a current spreading layer in the semiconductor layer beneath the plurality of mesa stripes;
wherein the region of the semiconductor layer is within an area bounded by the opening in the interlayer dielectric layer.

34. The semiconductor device structure of claim 33, wherein the opening in the interlayer dielectric layer overlaps the region of the semiconductor layer in which the current spreading layer is formed by a distance of about 5 to 10 microns.

35. semiconductor device structure of claim 25, wherein the additional mesa region has a length in the first direction parallel to the at least one of the mesa stripes that is less than a width of the at least one of the mesa stripes in a second direction perpendicular to the at least one of the mesa stripes.

36. The semiconductor device structure of claim 25, wherein the additional mesa region overlaps end surfaces of at least two of the plurality of the mesa stripes.

37. The semiconductor device structure of claim 25, wherein the additional mesa region comprises a mesa dam that surrounds the plurality of the mesa stripes.

38. The semiconductor device structure of claim 21, wherein the semiconductor device structure comprises a junction field effect transistor, JFET, device structure.

39. The semiconductor device structure of claim 21, wherein the semiconductor device structure comprises a metal oxide semiconductor field effect transistor, MOSFET, device structure.
